(19) United States
(12) Patent Application Publication
(10) Pub. No.: US 2026/0280555 A1
(43) Pub. Date: Sep. 17, 2026

(54) SYSTEM AND METHOD FOR AUTOMATED DYNAMIC CHARACTERIZATION OF HYBRID SWITCHES AND BUSBAR FOR USE THEREWITH

(71) Applicant: STMicroelectronics International N.V., Geneva (CH)

(72) Inventors: Rosario ATTANASIO, Barrington, IL (US); Harsha ADEMANE, Chicago, IL (US); Ryan SATTERLEE, Barrington, IL (US)

(21) Appl. No.: 19/076,216

(22) Filed: Mar. 11, 2025

(51) Int. Cl. H03K 17/567; H03K 17/16

(52) U.S. Cl. CPC H03K 17/567; H03K 17/163; H03K 2217/0036

(57) ABSTRACT

In accordance with various embodiments of the present disclosure, a system for dynamically characterizing switching behavior of power semiconductors is provided. In some embodiments, the system comprises a storage device for different sets of test parameters to be tested on a first power semiconductor switch of a first type and a second power semiconductor switch of a second type, each set of test parameters comprising a gate turn-on order, a gate turn-off order, a delay on duration, and a delay off duration; a processing element to retrieve the different sets of test parameters one at a time; gate drivers to, for each of the different sets of test parameters, receive signals corresponding to a retrieved set of test parameters and turning the first and second power semiconductor switches on and off accordingly; and a data capture device to capture data as the power semiconductor switches turn on and off.

### FIELD OF THE INVENTION

Example embodiments of the present disclosure relate generally to power semiconductors and, more particularly, to dynamically characterizing the switching behavior of power semiconductors.

### BACKGROUND

The development process of a power electronic inverter for automotive and industrial applications (such as electric vehicles (EVs) and hybrid electric vehicles (HEVs)) includes several crucial steps. One key step involves dynamically characterizing the switching behavior of power semiconductors. This is achieved through a double pulse test (DPT) setup, which includes essential components such as a capacitive energy storage device (dc-link capacitor), the power semiconductors to be tested (comprising at least one switch and one diode), and a load inductor.

Standards like IEC 60747-8 and IEC 60747-9 detail the test and measurement setup using silicon carbide (SiC) transistors and insulated-gate bipolar transistors (IGBTs), respectively. A current trend involves exploring the potential of a “hybrid switch” configuration that combines SiC and IGBT technology by paralleling multiple devices to leverage the advantages of each technology. Precise control of the turn-on and turn-off sequence of SiC and IGBT devices is crucial when using these technologies in parallel in a “hybrid switch.” The timing of turn-on and turn-off (between SiC and IGBT) significantly impacts the switch's dynamic characteristics (Eon/Eoff) and other properties like short-circuit capability.

In the context of power electronics, “Eon” refers to the turn-on switching energy loss, while “Eoff” represents the turn-off switching energy loss. This essentially measures the energy dissipated during the transition from off to on state (Eon) and from on to off state (Eoff) respectively. Both are important parameters when considering the efficiency of a power converter.

Dedicated gate drivers enable precise control of these timings to optimize switch efficiency. The turn-on and turn-off delay times can be adjusted with a certain resolution within a maximum window of 1.8 microseconds. It is important to characterize a hybrid switch to find optimum delay times. This can require numerous manual iterations and is therefore time-consuming and impractical.

Applicant has identified many technical challenges and difficulties associated with dynamically characterizing the switching behavior of power semiconductors. Through applied effort, ingenuity, and innovation, Applicant has solved problems related to dynamically characterizing the switching behavior of power semiconductors by developing solutions embodied in the present disclosure, which are described in detail below.

### BRIEF SUMMARY

Various embodiments described herein relate to systems and methods for dynamically characterizing the switching behavior of power semiconductors. Various embodiments described herein relate to busbars for such systems, methods, apparatuses, and computer program products.

In accordance with various embodiments of the present disclosure, a system for dynamically characterizing switching behavior of power semiconductors is provided. In some embodiments, the system comprises one or more storage devices to store a first plurality of different sets of test parameters to be tested on a first power semiconductor switch of a first type and a second power semiconductor switch of a second type, each of the first plurality of different sets of test parameters comprising a gate turn-on order for the first and second power semiconductor switches, a gate turn-off order for the first and second power semiconductor switches, a delay on duration, and a delay off duration; one or more processing elements to retrieve the first plurality of different sets of test parameters one at a time from the one or more storage devices; one or more gate drivers to, for each of the first plurality of different sets of test parameters retrieved by the one or more processing elements, receive one or more signals from the one or more processing elements corresponding to a retrieved set of test parameters and turning the first and second power semiconductor switches on and off according to the retrieved set of test parameters; and a data capture device to, for each of the first plurality of different sets of test parameters retrieved by the one or more processing elements, capture data from the first and second power semiconductor switches as the first and second power semiconductor switches turn on and off. The first plurality of different sets of test parameters has a first resolution. For each of the first plurality of different sets of test parameters retrieved by the one or more processing elements, the one or more processing elements analyzes the captured data to determine at least a corresponding turn-on switching energy loss (Eon) and a corresponding turn-off switching energy loss (Eoff). After the Eon and Eoff are determined for each of the first plurality of different sets of test parameters, the one or more processing elements identifies a sub-range of the first plurality of different sets of test parameters in which the Eon and Eoff are lower than in others of the first plurality of different sets of test parameters. The one or more processing elements creates a second plurality of different sets of test parameters covering the identified sub-range of the first plurality of different sets of test parameters, each of the second plurality of different sets of test parameters comprising a gate turn-on order for the first and second power semiconductor switches, a gate turn-off order for the first and second power semiconductor switches, a delay on duration, and a delay off duration. The second plurality of different sets of test parameters has a second resolution higher than the first resolution of the first plurality of different sets of test parameters. The one or more storage devices stores the second plurality of different sets of test parameters. The one or more processing elements retrieve the second plurality of different sets of test parameters one at a time from the one or more storage devices. The one or more gate drivers receives, for each of the second plurality of different sets of test parameters retrieved by the one or more processing elements, one or more signals from the one or more processing elements corresponding to a retrieved set of test parameters and turns the first and second power semiconductor switches on and off according to the retrieved set of test parameters. The data capture device captures, for each of the first plurality of different sets of test parameters retrieved by the one or more processing elements, data from the first and second power semiconductor switches as the first and second power semiconductor switches turn on and off. For each of the second plurality of different sets of test parameters retrieved by the one or more processing elements, the one or more processing elements analyzes the captured data to determine at least a corresponding turn-on switching energy loss (Eon) and a corresponding turn-off switching energy loss (Eoff). The one or more processing elements determines which of the second plurality of different sets of test parameters corresponds to a lowest Eon and a lowest Eoff.

In some embodiments, the one or more processing elements comprises a first processing element to retrieve the first plurality of different sets of test parameters one at a time from the one or more storage devices and a second processing element to provide the one or more signals corresponding to a retrieved set of test parameters to the one or more gate drivers.

In some embodiments, the first processing element comprises a personal computer and the second processing element comprises a microcontroller.

In some embodiments, the data capture device comprises an oscilloscope.

In some embodiments, the first power semiconductor switch comprises a silicon carbide transistor and the second power semiconductor switch comprises an insulated-gate bipolar transistor.

In accordance with various embodiments of the present disclosure, a method for dynamically characterizing switching behavior of power semiconductors is provided. In some embodiments, the method comprises storing, in one or more storage devices, a first plurality of different sets of test parameters to be tested on a first power semiconductor switch of a first type and a second power semiconductor switch of a second type, each of the first plurality of different sets of test parameters comprising a gate turn-on order for the first and second power semiconductor switches, a gate turn-off order for the first and second power semiconductor switches, a delay on duration, and a delay off duration, the first plurality of different sets of test parameters having a first resolution; retrieving, by one or more processing elements, the first plurality of different sets of test parameters one at a time from the one or more storage devices; for each of the first plurality of different sets of test parameters retrieved by the one or more processing elements, receiving, by one or more gate drivers, one or more signals from the one or more processing elements corresponding to a retrieved set of test parameters; turning, by the one or more gate drivers, the first and second power semiconductor switches on and off according to the retrieved set of test parameters; for each of the first plurality of different sets of test parameters retrieved by the one or more processing elements, capturing, by a data capture device to, data from the first and second power semiconductor switches as the first and second power semiconductor switches turn on and off; for each of the first plurality of different sets of test parameters retrieved by the one or more processing elements, analyzing, by the one or more processing elements, the captured data to determine at least a corresponding turn-on switching energy loss (Eon) and a corresponding turn-off switching energy loss (Eoff); after the Eon and Eoff are determined for each of the first plurality of different sets of test parameters, identifying, by the one or more processing elements, a sub-range of the first plurality of different sets of test parameters in which the Eon and Eoff are lower than in others of the first plurality of different sets of test parameters; creating, by the one or more processing elements, a second plurality of different sets of test parameters covering the identified sub-range of the first plurality of different sets of test parameters, each of the second plurality of different sets of test parameters comprising a gate turn-on order for the first and second power semiconductor switches, a gate turn-off order for the first and second power semiconductor switches, a delay on duration, and a delay off duration, the second plurality of different sets of test parameters having a second resolution higher than a first resolution of the first plurality of different sets of test parameters; storing, by the one or more storage devices, the second plurality of different sets of test parameters; retrieving, by the one or more processing elements, the second plurality of different sets of test parameters one at a time from the one or more storage devices; for each of the second plurality of different sets of test parameters retrieved by the one or more processing elements, receiving, by the one or more gate drivers receives, one or more signals from the one or more processing elements corresponding to a retrieved set of test parameters; turning, by the one or more gate drivers, the first and second power semiconductor switches on and off according to the retrieved set of test parameters; for each of the second plurality of different sets of test parameters retrieved by the one or more processing elements, capturing, by the data capture device, data from the first and second power semiconductor switches as the first and second power semiconductor switches turn on and off; for each of the second plurality of different sets of test parameters retrieved by the one or more processing elements, analyzing, by the one or more processing elements, the captured data to determine at least a corresponding turn-on switching energy loss (Eon) and a corresponding turn-off switching energy loss (Eoff); and determining, by the one or more processing elements, which of the second plurality of different sets of test parameters corresponds to a lowest Eon and a lowest Eoff.

In accordance with various embodiments of the present disclosure, a busbar assembly is provided. In some embodiments, the busbar assembly comprises a front busbar having an elongated top conductor, and elongated middle conductor substantially parallel to the top conductor, and an elongated bottom conductor substantially parallel to the top conductor and the middle conductor; a planar rear busbar positioned substantially parallel to the front busbar and electrically connected to the bottom conductor of the front busbar; and a planar insulator positioned between the front busbar and the rear busbar. The front busbar is adapted to receive a plurality of high side switching devices mounted to the top conductor and the middle conductor. The front busbar is adapted to receive a plurality of low side switching devices mounted to the middle conductor and the bottom conductor.

The above summary is provided merely for purposes of summarizing some example embodiments to provide a basic understanding of some aspects of the disclosure. Accordingly, it will be appreciated that the above-described embodiments are merely examples and should not be construed to narrow the scope or spirit of the disclosure in any way. It will also be appreciated that the scope of the disclosure encompasses many potential embodiments in addition to those here summarized, some of which will be further described below.

### BRIEF DESCRIPTION OF THE DRAWINGS

The description of the illustrative embodiments may be read in conjunction with the accompanying figures. It will be appreciated that, for simplicity and clarity of illustration, elements illustrated in the figures have not necessarily been drawn to scale, unless described otherwise. For example, the dimensions of some of the elements may be exaggerated relative to other elements, unless described otherwise. Embodiments incorporating teachings of the present disclosure are shown and described with respect to the figures presented herein, in which:

FIG. 1 is a perspective view of an example busbar assembly, with a plurality of power semiconductor switches mounted thereto, in accordance with some embodiments of the present disclosure;

FIG. 2 is another perspective view of the example busbar assembly of FIG. 1 with the power semiconductor switches removed;

FIG. 3 is an exploded perspective view of the example busbar assembly of FIG. 1;

FIG. 4 is a front perspective view of the front busbar of the example busbar assembly of FIG. 1;

FIG. 5 is a rear perspective view of the front busbar of the example busbar assembly of FIG. 1;

FIGS. 6A and 6B are front and rear views, respectively, of the example busbar assembly of FIG. 1 showing current flow therethrough;

FIG. 7 is a perspective view of an example busbar assembly, in accordance with some alternative embodiments of the present disclosure; and

FIG. 8 is a block diagram of an example system for dynamically characterizing the switching behavior of power semiconductors.

### DETAILED DESCRIPTION OF THE INVENTION

Some embodiments of the present disclosure will now be described more fully hereinafter with reference to the accompanying drawings, in which some, but not all embodiments of the disclosure are shown. Indeed, these disclosures may be embodied in many different forms and should not be construed as limited to the embodiments set forth herein; rather, these embodiments are provided so that this disclosure will satisfy applicable legal requirements. Like numbers refer to like elements throughout.

As used herein, terms such as “front,” “rear,” “top,” etc. are used for explanatory purposes in the examples provided below to describe the relative position of certain components or portions of components. Furthermore, as would be evident to one of ordinary skill in the art in light of the present disclosure, the terms “substantially” and “approximately” indicate that the referenced element or associated description is accurate to within applicable engineering tolerances.

As used herein, the term “comprising” means including but not limited to and should be interpreted in the manner it is typically used in the patent context. Use of broader terms such as comprises, includes, and having should be understood to provide support for narrower terms such as consisting of, consisting essentially of, and comprised substantially of.

The phrases “in one embodiment,” “according to one embodiment,” and the like generally mean that the particular feature, structure, or characteristic following the phrase may be included in at least one embodiment of the present disclosure, and may be included in more than one embodiment of the present disclosure (importantly, such phrases do not necessarily refer to the same embodiment).

The word “example” or “exemplary” is used herein to mean “serving as an example, instance, or illustration.” Any implementation described herein as “exemplary” is not necessarily to be construed as preferred or advantageous over other implementations.

If the specification states a component or feature “may,” “can,” “could,” “should,” “would,” “preferably,” “possibly,” “typically,” “optionally,” “for example,” “often,” or “might” (or other such language) be included or have a characteristic, that a specific component or feature is not required to be included or to have the characteristic. Such a component or feature may be optionally included in some embodiments, or it may be excluded.

Various embodiments of the present disclosure overcome the above technical challenges and difficulties and provide various technical improvements and advantages based on, for example, but not limited to, providing example systems and methods for dynamically characterizing the switching behavior of power semiconductors and providing busbars for such systems and methods.

To characterize a hybrid switch effectively, an automated measurement system is desirable to avoid the time-consuming and impractical manual iterations required to find optimum delay times. Furthermore, the results of dynamic characterization are heavily influenced by the parasitic inductance of the gate loop and the DC-Link to Device Under Test (DUT) loop. Therefore, designing a busbar system that facilitates connecting multiple devices in parallel using a scalable and modular approach for the gate driver board connection is desirable.

Various embodiments of the present disclosure are directed to a busbar design for double pulse test of hybrid power semiconductor switches, such as but not limited to IGBTs and SiC devices. Such power semiconductor switches typically comprise multiple high side T-pack package devices connected in parallel and multiple low side T-pack package devices connected in parallel. Various embodiments of the present disclosure are also directed to the automated extraction of the turn-on (Eon) and turn-off (Eoff) energies as a function of the turn on and turn off delay time values (between IGBTs and SiC devices).

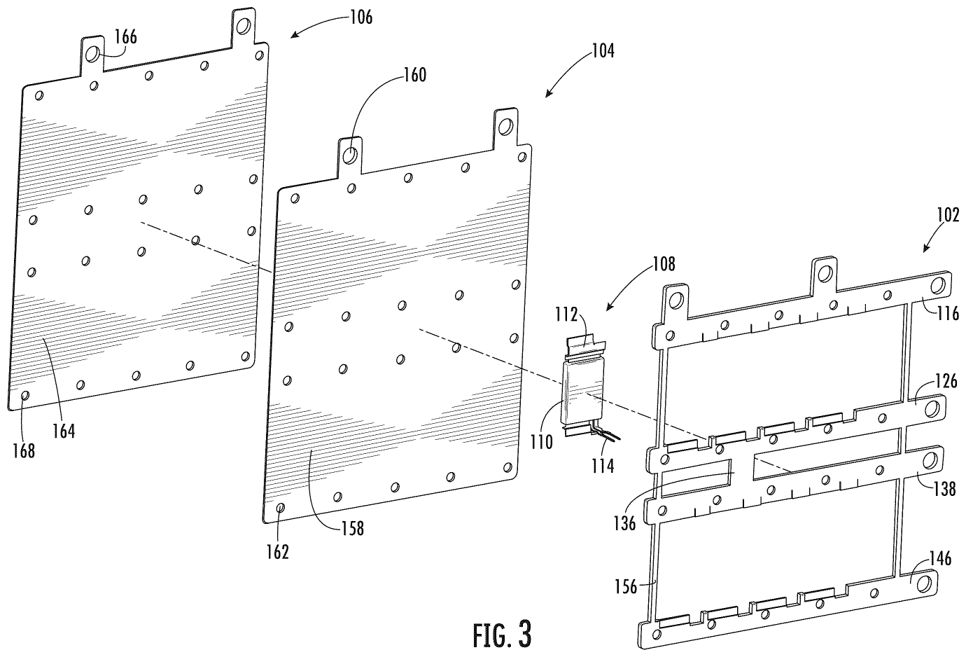

A “T-pack” in semiconductor power device packaging refers to a type of package design where the power device die is mounted on a lead frame with a “T” shaped configuration, allowing for efficient heat dissipation and electrical connections, often used for high-power applications like IGBTs due to its ability to handle significant current flow while maintaining good thermal management. Such T-pack devices are illustrated in the figures mounted to the example busbar assembly. The structure of the T-pack devices is best seen in FIG. 3. As seen in FIG. 3, a power semiconductor switch 108 comprises a wide, flat base (not visible) upon which the die 110 is attached, with upper and lower vertical flanges 112 providing drain and source connections to the busbar assembly and gate and source terminals 114 extending perpendicularly from the die 110.

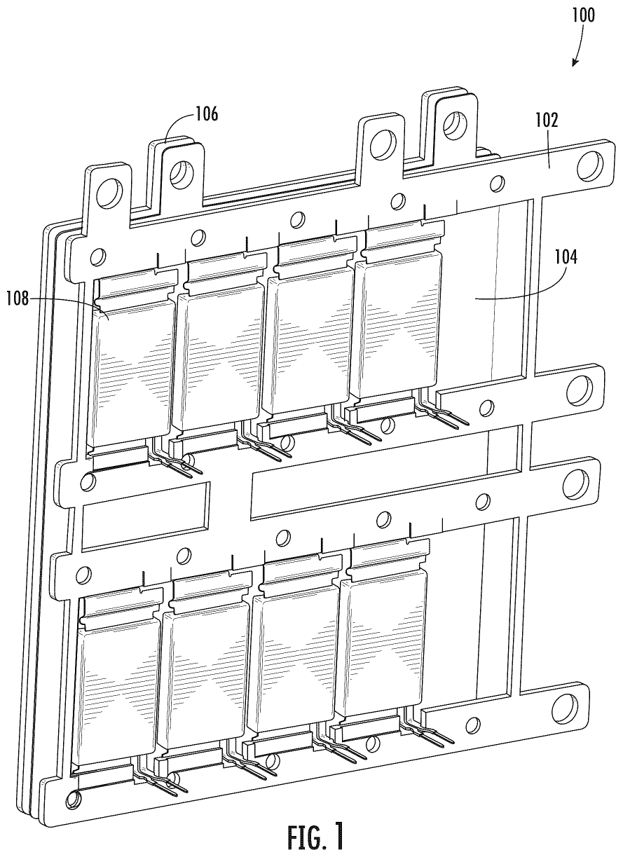

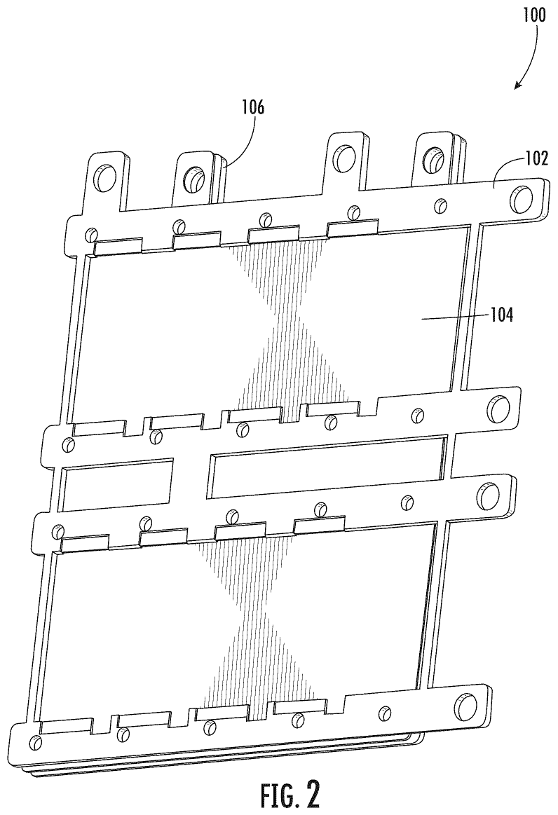

FIGS. 1-3 illustrate an example busbar assembly, in accordance with some embodiments of the present disclosure. The busbar assembly 100 of FIGS. 1-3 comprises a front busbar 102, a rear busbar 106, and a dielectric insulator positioned therebetween. Eight power semiconductor switches 108 are mounted to the front busbar 102 in FIG. 1. The four power semiconductor switches 108 connected in parallel on the top are termed high side devices, while the four power semiconductor switches 108 connected in parallel on the bottom are termed low side devices.

In various embodiments, the front busbar 102 and the rear busbar 106 are constructed of any suitable conductive material, such as copper. The insulator 104 is interposed between the front and rear busbars to prevent any unintended electrical connection between the front and rear busbars. In various embodiments, the insulator 104 is constructed of any suitable dielectric material.

In various embodiments, the front busbar 102 comprises an elongated generally horizontal top conductor 116, an elongated generally horizontal middle two-part conductor, and an elongated generally horizontal bottom conductor 146. In the illustrated embodiment, the middle two-part conductor comprises an elongated generally horizontal middle-top conductor 126, an elongated generally horizontal middle-bottom conductor 138, and a generally vertical conductive center link or bridge 136 electrically connecting the middle-top conductor 126 and the middle-bottom conductor 138. In other embodiments (not illustrated), the middle conductor may comprise a single generally horizontal conductor. Connection terminals 118 extend from the top edge of the top conductor 116 to enable connection of the front busbar 102 to a high voltage source, such as a high voltage capacitor.

The top conductor 116, the middle-top conductor 126, the middle-bottom conductor 138, and the bottom conductor 146 are held together during the assembly phase (i.e., as the power semiconductor switches 108 are soldered to the front busbar 102) by the side edge links or bars 156. In various embodiments, the side edges links 156 are readily removable after the assembly phase is completed, such as by cutting the side edge links 156 away from the rest of the front busbar 102 with metal snips.

As seen in FIG. 3, the insulator 104 comprises a planar main body 158, various holes 162 aligned with corresponding holes in the front busbar 102 and with corresponding holes in the rear busbar 106, and tabs 160 extending from the top edge. Also as seen in FIG. 3, the rear busbar 106 comprises a planar main body 164 with various holes 168 defined therein. Connection terminals 166 extend from the top edge of the rear busbar 106 to enable connection of the rear busbar 106 to a high voltage source, such as a high voltage capacitor.

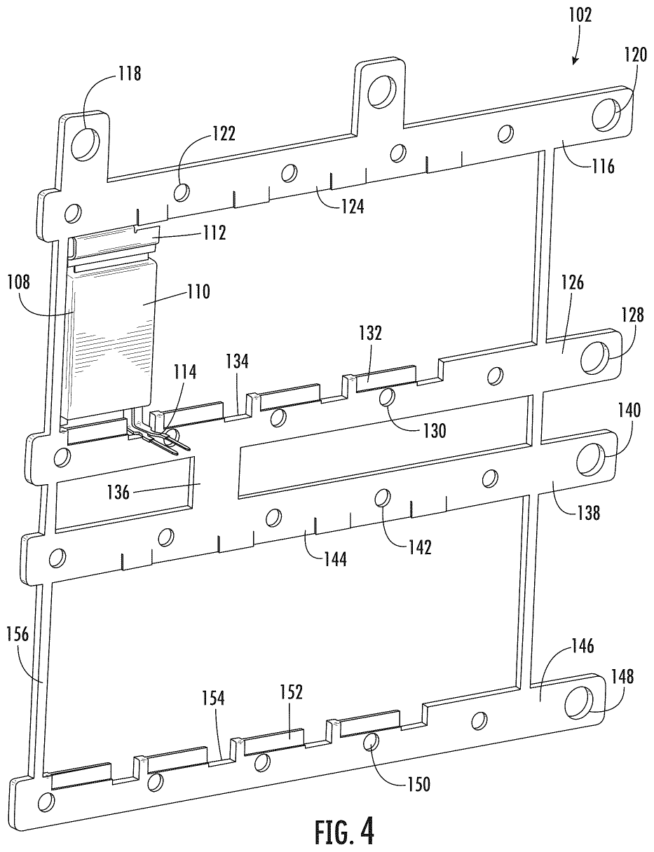

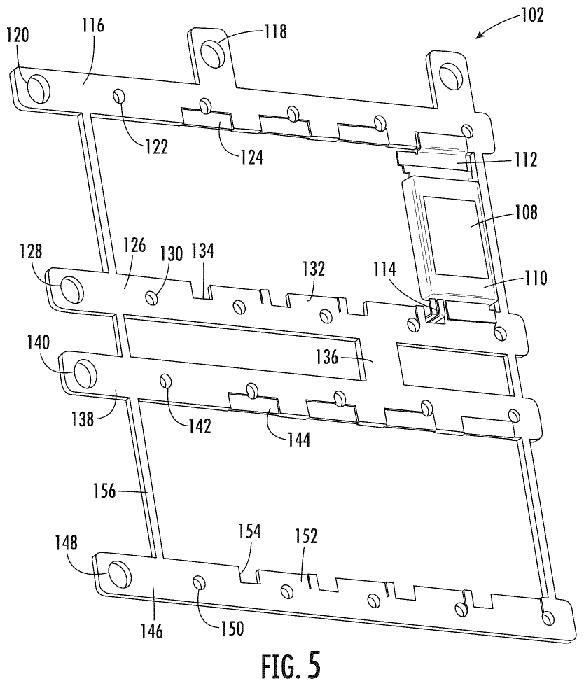

Referring now to FIGS. 4 and 5, the front busbar 102 is described in further detail. As seen in FIGS. 4 and 5, a plurality of mounting recesses 124 are defined in the top conductor 116, a plurality of mounting recesses 132 are defined in the middle-top conductor 126, a plurality of mounting recesses 144 are defined in the middle-bottom conductor 138, and a plurality of mounting recesses 152 are defined in the bottom conductor 146 of the front busbar 102. The plurality of mounting recesses 124 defined in the top conductor 116 and the plurality of mounting recesses 132 defined in the middle-top conductor 126 are adapted to receive the respective upper and lower vertical flanges 112 of the high side switching devices. The plurality of mounting recesses 144 defined in the middle-bottom conductor 138 and the plurality of mounting recesses 152 defined in the bottom conductor 146 are adapted to receive the respective upper and lower vertical flanges 112 of the low side switching devices. The mounting recesses are sized, shaped, and positioned to readily receive the vertical flanges 112 of the power semiconductor switches 108 and help maintain the position of the power semiconductor switches 108 as the power semiconductor switches 108 are soldered to the front busbar 102. In various embodiments, as shown in FIGS. 4 and 5, the mounting recesses may be defined on both the front and back side of the front busbar 102 to enable the power semiconductor switches 108 to be affixed to either the front side or the back side of the front busbar 102.

As seen in FIGS. 4 and 5, a plurality of holes 122 are defined in the top conductor 116, a plurality of holes 130 are defined in the middle-top conductor 126, a plurality of holes 142 are defined in the middle-bottom conductor 138, and a plurality of holes 150 are defined in the bottom conductor 146 of the front busbar 102.

As seen in FIGS. 4 and 5, a plurality of wire gaps 134 are defined in the middle-top conductor 126 and a plurality of wire gaps 154 are defined in the bottom conductor 146 of the front busbar 102. Each of the wire gaps is adjacent to a corresponding mounting recess. The wire gaps 134 defined in the middle-top conductor 126 are sized, shaped, and positioned to allow the gate and source terminals 114 of respective ones of the high side switching devices to pass therethrough to avoid electrical contact between the middle-top conductor 126 and the gate and source terminals 114, and the wire gaps 154 defined in the bottom conductor 146 are sized, shaped, and positioned to allow the gate and source terminals 114 of respective ones of the low side switching devices to pass therethrough to avoid electrical contact between the bottom conductor 146 and the gate and source terminals 114.

In various embodiments, a plurality of inductor connection points are defined in a same corresponding end of each of the top conductor, the middle-top conductor, the middle-bottom conductor, and the bottom conductor of the front busbar. As seen in FIGS. 4 and 5, an inductor connection point 120 is defined in the top conductor 116, an inductor connection point 128 is defined in the middle-top conductor 126, an inductor connection point 140 is defined in the middle-bottom conductor 138, and an inductor connection point 148 is defined in the bottom conductor 146 of the front busbar 102. The inductor connection points enable a test inductor to be connected to the top conductor 116 and the middle-top conductor 126 via inductor connection points 120, 128 such that the test inductor is in parallel to the high side devices or to the middle-bottom conductor 138 and the bottom conductor 146 via inductor connection points 140, 148 such that the test inductor is in parallel to the low side devices.

When assembled, the rear busbar 106 is electrically connected to the bottom conductor 146 of the front busbar 102, such as via screws placed through the holes 150 in the bottom conductor 146, the lowest row of holes 162 in the insulator 104, and the lowest row of holes 168 in the rear busbar 106. The other rows of holes 162 in the insulator 104 and the other rows of holes 168 in the rear busbar 106 are used for mechanical, but not electrical, connection of the front busbar 102, the insulator 104, and the rear busbar 106. Specifically, a plurality of non-conductive fasteners (e.g., plastic or ceramic screws) are used to connect (i) the holes 122 defined in the top conductor 116, the top row of holes 162 in the insulator 104, and the top row of holes 168 in the rear busbar 106, (ii) the holes 130 defined in the middle-top conductor 126, the second from the top row of holes 162 in the insulator 104, and the second from the top row of holes 168 in the rear busbar 106, and (iii) the holes 142 defined in the middle-bottom conductor 138, the second from the bottom row of holes 162 in the insulator 104, and the second from bottom top row of holes 168 in the rear busbar 106. The non-conductive fastener ensure electrical insulation while providing the necessary force to hold the front busbar 102, the insulator 104, and the rear busbar 106 together.

Once the assembly phase is completed and the side edge links 156 are removed, the top conductor116 of the front busbar 102 connects the drain of the high side power devices to a high voltage source, such as a high voltage capacitor, and to a test inductor. The middle two-part conductor of the front busbar connects the sources of the high side power devices to the drains of low side devices and the inductor. The bottom conductor 146 of the front busbar 102 connects the sources of the low side power devices and the inductor (if desired, for a diode characterization test).

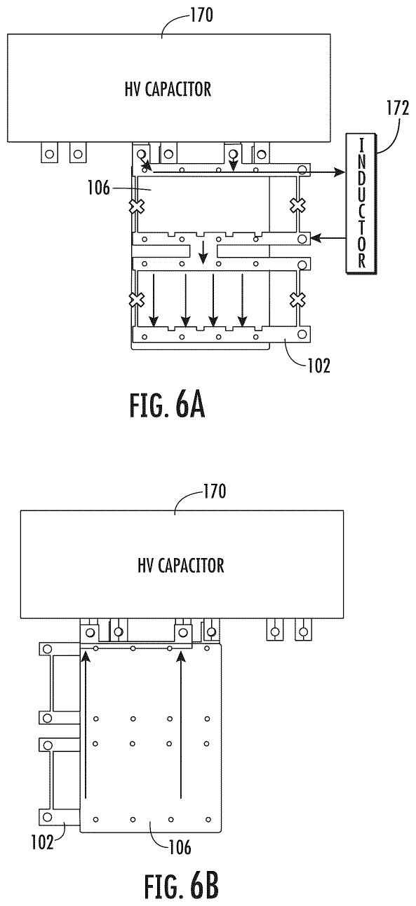

Referring now to FIGS. 6A and 6B, arrows indicate the current flow through a test assembly (the power semiconductor switches and the insulator are omitted from FIGS. 6A and 6B for clarity). As seen in FIGS. 6A and 6B, current flows from a high voltage (HV) capacitor 170 (or other suitable HV source) to the top conductor 116, to the test inductor 172, to the middle-top conductor 126, through the bridge 136 to the middle-bottom conductor 138, through the low side power devices (omitted for clarity), through screws or the like (not illustrated) to the lower end of the rear busbar 106, and up the rear busbar 106 to the HV capacitor 170. A coil of wire (not illustrated) may be wrapped around the bridge 136 to form a Rogowski coil for measurement of the total high side and low side hybrid switch current or single switch current.

The modular approach of embodiments of the disclosure enables a varying number of T-pack power devices to be soldered to the same front busbar. For example, in the busbar assembly of FIGS. 1-6, from one to five high side devices and from one to five low side devices can be soldered to the front busbar 102. In various embodiments, the width of the busbar assembly can be increased or decreased based on the number of power devices to be connected in parallel.

Once the assembly phase is completed, a first gate driver board (or simply “gate driver”) is electrically connected to all of the high side devices and a second gate driver board is electrically connected to all of the low side devices to perform the automated dynamic characterization. Such a gate driver board contains one or more gate driver components (and other electronic components) mounted on a printed circuit board. The gate driver boards are connected such that the gate driver boards are substantially perpendicular to the busbar assembly. Various embodiments do not require the use of wires to connect the gate and source of the power devices to the gate driver. In various embodiments, the gate and source terminals 114 are soldered directly to the gate driver board so to minimize the parasitic inductance of the gate loop.

In one specific example embodiment, the assembly of the busbar assembly comprises some or all of the following steps:
a) Position the top busbar on a heating plate;
b) Apply low temperature solder paste with a melting point of ~140C to the T-Pak positioning grooves of the top bus bar;
c) Position each T-pack used for the high side switch to span from the top conductor to the middle-top conductor, and such that the upper and lower vertical flanges are within corresponding mounting recesses filled with solder paste;
d) Position each T-pack used for the low side switch to span from the middle-bottom conductor to the bottom conductor, and such that the upper and lower vertical flanges are within corresponding mounting recesses filled with solder paste;
e) Preheat to 100C at a rate of 1-3 C per second;
f) Ramp up to soak zone from 100C to 120C at 0.3-0.7C per seconds;
g) Ramp up to peak temperature of 165C in 80s max;
h) Cool down at 2C/s until the unit reaches 25C (the duration and temperatures of the soldering profile can be the ones provided by the solder paste manufacturer);
i) Remove the part from the heating plate;
j) Remove the side edges links;
k) Position the insulator between the top busbar and the bottom busbar;
l) Connect the top busbar and the bottom busbar together using the top, mid, and bottom side screw mounting holes; and
m) Connect the top busbar and the bottom busbar to the HV capacitor using the connection terminals.

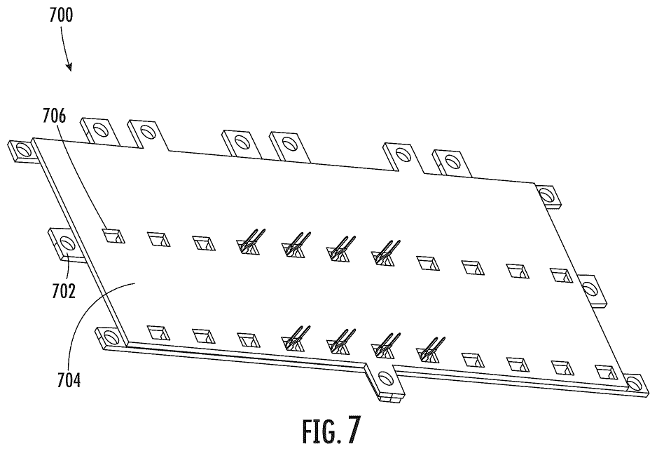

Referring now to FIG. 7, an example busbar assembly is illustrated in accordance with some alternative embodiments of the present disclosure. In the illustrated embodiments, the busbar assembly 700 comprises a rear busbar 702 to which the power devices are mounted and a front busbar 704 that provides the return path for the current. In other words, the relative positions of the front busbar and the rear busbar are swapped from the embodiment of FIGS. 1-6. The insulator is omitted from FIG. 7 for clarity but would be positioned between the rear busbar 702 and the front busbar 704. In this embodiment, the rear busbar 702 has substantially the same structure as the front busbar 102 of FIGS. 1-6. In this embodiment, the front busbar 704 has substantially the same structure as the rear busbar 106 of FIGS. 1-6, except that the front busbar 704 has a plurality of wire holes 706 aligned with the wire gaps of the rear busbar 702 (which are substantially the same as the wire gaps 134, 154 of the front busbar 102 of FIGS. 1-6) to enable the and gate and source terminals 114 of the power devices to extend through the front busbar 704 and be connected to the gate drivers. In various embodiments, the insulation layer can be inserted between the top and bottom busbars or laminated into a unified structure. The alternative arrangement of FIG. 7 allows the T-Pack devices to be soldered or sintered to a complex cooling structure.

Embodiments of the present disclosure are also directed to systems and method for the automated extraction of Eon and Eoff for hybrid switches as a function of the turn on and turn off delay time values (e.g., between IGBTs and SiC devices). Automatically testing a large number of different delay times enables automatic identification of the optimum driving delay times for any arbitrary hybrid switch configuration.

Table 1 below illustrates an example of test parameters that may be used to automatically identify optimum driving delay times. In some embodiments, the range of the tested delay is +/−1.8 microseconds (us) (or +/−1800 nanoseconds (ns)), although in the example of Table 1 the range is 0-1.8 ns. Each row in the table represents a set of test parameters that are used for a respective test. In the example of Table 1 there are ten sets of test parameters, although fewer or (more likely) more sets would be used. In the example of Table 1, the gaps between the different delay times are not equal—the larger delay times have larger gaps since the larger delay times are less likely to be the optimum driving delay times. In Table 1, Vds is the voltage applied to the devices in volts, Ids is the current through the devices in amps, Delay refers to the gate drive signal timing between the device that turns on first and the one that follows and the device that turns, off first and the one that follows, in nanoseconds, Ton1 is Ton1 is the duration of the first pulse applied in the double pulse test in microseconds, Toff1 is the off time following the first pulse in microseconds, Ton2 is the duration of the second pulse applied after the Toff1 in microseconds, and Toff2 is he duration of the off time applied after Ton2 in microseconds. As an example of the Delay, Table 1 shows Device ON First=SiC (which means that the delay is applied to the device that turns on after the SiC (IGBT in this case)) and Device OFF First=IGBT (which means that the delay at turn off is applied to the device that is turned off after the IGBT ((SiC in this case)). Table 1 shows the only delay time that changes once the test current value has been defined. The test current value defines Ton1, Ton2, Toff1, Toff2. Once these are defined, Delay is swept. The process is then repeated for the next test current.

TABLE 1

| | | Device | Device | | | | | |
|---|---|---|---|---|---|---|---|---|
| | | ON | OFF | Delay | Ton1 | Toff1 | Ton2 | Toff2 |
| Vds | Ids | First | First | (ns) | (us) | (us) | (us) | (us) |
| 400 | 90 | SiC | IGBT | 1800 | 10 | 8 | 8 | 10 |
| 400 | 90 | SiC | IGBT | 1200 | 10 | 8 | 8 | 10 |
| 400 | 90 | SiC | IGBT | 960 | 10 | 8 | 8 | 10 |
| 400 | 90 | SiC | IGBT | 840 | 10 | 8 | 8 | 10 |
| 400 | 90 | SiC | IGBT | 600 | 10 | 8 | 8 | 10 |
| 400 | 90 | SiC | IGBT | 480 | 10 | 8 | 8 | 10 |
| 400 | 90 | SiC | IGBT | 360 | 10 | 8 | 8 | 10 |
| 400 | 90 | SiC | IGBT | 240 | 10 | 8 | 8 | 10 |
| 400 | 90 | SiC | IGBT | 120 | 10 | 8 | 8 | 10 |
| 400 | 90 | SiC | IGBT | 0 | 10 | 8 | 8 | 10 |

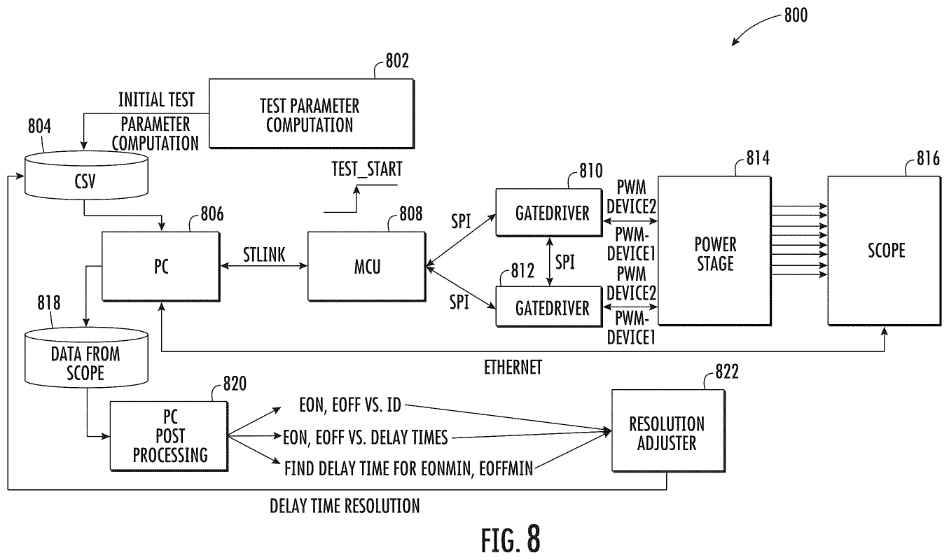

FIG. 8 illustrates a test system and process 800 for automated measurements of Eon/Eoff for hybrid switches controlled by a gate driver with variable t-on and t-off delay times for the various devices. As illustrated in FIG. 8, a number of different sets of test parameters, which include different delay times to be tested are determined at block 802 and stored in a storage device, such as a database 804, in any suitable format, such as a csv file. The sets of test parameters are provided to a processing device, such as a personal computer (PC) 806 which, in various embodiments, manages the test procedure.

One set at a time, the PC 806 communicates test parameters for each test scenario to a processing device, such as a microcontroller (MCU) 808. While FIG. 8 illustrates two different processing devices, PC 806 and MCU 808, in alternative embodiments a single processing device or more than two processing devices may be used. In various embodiments, the MCU 808 controls two gate drivers 810, 812 which in turn control the power stage 814 which comprises the switches to be tested (i.e., the T-pack IGBTs and SiC devices attached to the bus bar assembly described above), turning the switches on and off according to the test parameters. In various embodiments, gate driver 810 drives the high side devices and gate drive 812 drives the low side devices.

In some embodiments, the gate driver boards 810, 812 receive pulse width modulated (PWM) input signals from the MCU 808 via a serial peripheral interface (SPI) protocol. In various embodiments, the gate driver boards 810, 812 each have a plurality of outputs that can be configured to drive either an IGBT or SiC device by connecting the output terminal of the board to the proper control pins of the gate driver directly on the PCB. This allows the SiC and IGBTs to be positioned arbitrarily when paralleling the devices on the top busbar. In some embodiments, the number of outputs on the gate driver boards is variable from one to four, but any suitable number of outputs can be provided to support a higher number of paralleled devices. In various embodiments, the modular design of various embodiments of the present disclosure allows testing of multiple inverter legs in the same busbar assembly using the pluggable gate driver boards.

The outputs of the power stage 814 are supplied to a data collection device, such as an oscilloscope 816. The output of the oscilloscope 816 is provided to the PC 806 which stores the data in in a storage device, such as a database 818. While FIG. 8 illustrates two different data storage devices 804, 818, in alternative embodiments a single data storage device or more than two data storage devices may be used. The PC 806 performs post-processing on the data from the oscilloscope 816 in which the Eon and Eoff values are determined for each of the test scenarios. More specifically, in some embodiments the post-processing determines Eon and Eoff versus device current, Eon and Eoff versus delay times, and the delay time corresponding to the minimum Eon and the minimum Eoff, for each of the test scenarios. In various embodiments, post processing determines Eon and Eoff as a function of the delay time (turn on delay time for Eon and turn off delay time for Eoff) for multiple current levels. For example for a 1000A system, we can select ten current levels from 100A to 1000A.

Typically, the test scenarios can be time consuming and produce a large amount of data. As such, in various embodiments an initial batch of test scenarios are used which cover a wide range of different delay times with relatively greater gaps between each specific test scenario (i.e., relatively low resolution). This is seen in Table 1 in which the smallest gap between two adjacent delay times is 120 ns. In various embodiments, a resolution adjuster module 822 (which may be executed by the PC 806 or some other processing device)) analyses the post-processed data to identify a sub-range of delay times in which the Eon and Eoff values (and optionally other values) are more favorable. The resolution adjuster then focuses in on the identified sub-range and identifies a number of different delay times within this smaller sub-range (so relatively high resolution) to use in a next round of testing.

Table 2 below illustrates an example of test parameters created by the resolution adjuster module 822. In the example of Table 2, the initial batch of test scenarios identified that the delay time corresponding to the minimum Eon and the minimum Eoff was 360 ns. In this example embodiment, the resolution adjuster module 822 identified a sub-range of delay times based on the closest delay times to 360 ns, which in this case was 240 ns and 480 ns. The resolution adjuster module 822 then divided the sub-range of 240-400 ns into a plurality of sets of test parameters with gaps between the delay times of only 30 ns (as compared to 120 ns in the initial batch of testing). Any other suitable method of resolving the data to focus in on more narrow range for subsequent batch(es) of testing may be used.

TABLE 2

| | | Device | Device | | | | | |
|---|---|---|---|---|---|---|---|---|
| | | ON | OFF | | Ton1 | Toff1 | Ton2 | Toff2 |
| Vds | Ids | First | First | Delay | (us) | (us) | (us) | (us) |
| 400 | 90 | SiC | IGBT | 480 | 10 | 8 | 8 | 10 |
| 400 | 90 | SiC | IGBT | 450 | 10 | 8 | 8 | 10 |
| 400 | 90 | SiC | IGBT | 420 | 10 | 8 | 8 | 10 |
| 400 | 90 | SiC | IGBT | 390 | 10 | 8 | 8 | 10 |
| 400 | 90 | SiC | IGBT | 360 | 10 | 8 | 8 | 10 |
| 400 | 90 | SiC | IGBT | 330 | 10 | 8 | 8 | 10 |
| 400 | 90 | SiC | IGBT | 300 | 10 | 8 | 8 | 10 |
| 400 | 90 | SiC | IGBT | 270 | 10 | 8 | 8 | 10 |
| 400 | 90 | SiC | IGBT | 240 | 10 | 8 | 8 | 10 |

In various embodiments, the resolution adjuster module 822 may iterate its process multiple times to test even more narrow ranges of delay times with even higher resolution.

The busbar assembly of various embodiments of the present disclosure allows the connection of a varying arbitrary number of T-Pak devices in parallel forming a Hybrid Switch or standard switch (by paralleling either SiC or IGBTs), minimizes the parasitic inductances for easy characterization of hybrid switches, allows the connection of gate driver boards using a modular approach, allows for a simple and fast lab assembly procedure of a DPT platform with T-Pak devices, can be implemented in separate parts (front and rear busbars) or in a unified structure using lamination technique for sintering of the parts on the base plate of a cooling system, allows arbitrary positioning of the SiC and IGBT switches within a hybrid switch configuration, and minimizes the parasitic inductance of the gate loop. The automated test procedure of various embodiments of the present disclosure allows the fast extraction of the optimal control sequence to maximize the efficiency of the chosen hybrid switch configuration.

In various embodiments, the controller or other processing elements described herein, such as the control circuitry, may include one or more processors, input/output circuitry, data storage media, communications circuitry, and/or other components configured to perform compute operations. In some embodiments, the data storage media may be configured to store information, data, content, applications, instructions, or the like, for enabling the processing elements described herein to carry out various functions. As such, in some embodiments, the controller or other processing elements described herein may be referred to as functional logic. The controller or other processing elements described herein may be embodied in a number of different ways, for example, in some embodiments, the controller or other processing elements described herein may include one or more processing devices configured to perform independently. Additionally or alternatively, in some embodiments, the controller or other processing elements described herein may include one or more processor(s) configured in tandem via a bus to enable independent execution of instructions, pipelining, and/or multithreading. The use of the terms “controller,” “processor,” “control circuitry,” and “processing circuitry” should be understood to include a single core processor, a multi-core processor, multiple processors internal to the processing elements described herein, and/or one or more remote or “cloud” processor(s) external to the processing elements described herein.

In an example embodiment, the controller or other processing elements described herein may be configured to execute instructions stored in the data storage media or otherwise accessible to the processor. Alternatively or additionally, the controller or other processing elements described herein in some embodiments is configured to execute hard-coded functionality. As such, whether configured by hardware or software methods, or by a combination thereof, the controller or other processing elements described herein represent an entity (e.g., physically embodied in circuitry) capable of performing operations according to an embodiment of the present disclosure while configured accordingly. Alternatively or additionally, as another example in some example embodiments, when the controller or other processing elements described herein is embodied as an executor of software instructions, the instructions specifically configure the controller or other processing elements described herein to perform the algorithms embodied in the specific operations described herein when such instructions are executed.

The use of the term “circuitry” as used herein with respect to components of the apparatus should therefore be understood to include particular hardware configured to perform the functions associated with the particular circuitry as described herein. The term “circuitry” should be understood broadly to include hardware and, in some embodiments, software for configuring the hardware. For example, in some embodiments, “circuitry” may include processing circuitry, storage media, network interfaces, input/output devices, and the like.

As described above and as will be appreciated based on this disclosure, embodiments of the present disclosure may be configured as methods, devices, backend network devices, and the like. Accordingly, embodiments may comprise various means including entirely of hardware or any combination of software and hardware. Furthermore, embodiments may take the form of a computer program product on at least one non-transitory computer-readable storage medium having computer-readable program instructions (e.g., computer software) embodied in the storage medium. Similarly, embodiments may take the form of a computer program code stored on at least one non-transitory computer-readable storage medium. Any suitable computer-readable storage medium may be utilized including non-transitory hard disks, CD-ROMs, flash memory, optical storage devices, or magnetic storage devices.

### CONCLUSION

Many modifications and other embodiments of the disclosures set forth herein will come to mind to one skilled in the art to which these disclosures pertain having the benefit of teachings presented in the foregoing descriptions and the associated drawings. Although the figures only show certain components of the apparatus and systems described herein, it is understood that various other components may be used in conjunction with the system. Therefore, it is to be understood that the disclosures are not to be limited to the specific embodiments disclosed and that modifications and other embodiments are intended to be included within the scope of the appended claims. Moreover, the steps in the method described above may not necessarily occur in the order depicted in the accompanying diagrams, and in some cases one or more of the steps depicted may occur substantially simultaneously, or additional steps may be involved. Although specific terms are employed herein, they are used in a generic and descriptive sense only and not for purposes of limitation.

While various embodiments in accordance with the principles disclosed herein have been shown and described above, modifications thereof may be made by one skilled in the art without departing from the spirit and the teachings of the disclosure. The embodiments described herein are representative only and are not intended to be limiting. Many variations, combinations, and modifications are possible and are within the scope of the disclosure. Alternative embodiments that result from combining, integrating, and/or omitting features of the embodiment(s) are also within the scope of the disclosure. Accordingly, the scope of protection is not limited by the description set out above.

Additionally, the section headings used herein are provided for consistency with the suggestions under 37 C.F.R. 1.77 or to otherwise provide organizational cues. These headings shall not limit or characterize the disclosure(s) set out in any claims that may issue from this disclosure.

While this detailed description has set forth some embodiments of the present disclosure, the appended claims cover other embodiments of the present disclosure which differ from the described embodiments according to various modifications and improvements. For example, the appended claims can cover any system, device, or method of dynamically characterizing the switching behavior of power semiconductors.

Within the appended claims, unless the specific term “means for” or “step for” is used within a given claim, it is not intended that the claim be interpreted under 35 U.S.C. 112, paragraph 6.

What is claimed is:

1. A system for dynamically characterizing switching behavior of power semiconductors, the system comprising:
one or more storage devices to store a first plurality of different sets of test parameters to be tested on a first power semiconductor switch of a first type and a second power semiconductor switch of a second type, each of the first plurality of different sets of test parameters comprising a gate turn-on order for the first and second power semiconductor switches, a gate turn-off order for the first and second power semiconductor switches, a delay on duration, and a delay off duration;
one or more processing elements to retrieve the first plurality of different sets of test parameters one at a time from the one or more storage devices;
one or more gate drivers to, for each of the first plurality of different sets of test parameters retrieved by the one or more processing elements, receive one or more signals from the one or more processing elements corresponding to a retrieved set of test parameters and turning the first and second power semiconductor switches on and off according to the retrieved set of test parameters; and
a data capture device to, for each of the first plurality of different sets of test parameters retrieved by the one or more processing elements, capture data from the first and second power semiconductor switches as the first and second power semiconductor switches turn on and off;
wherein the first plurality of different sets of test parameters has a first resolution;
wherein, for each of the first plurality of different sets of test parameters retrieved by the one or more processing elements, the one or more processing elements analyzes the captured data to determine at least a corresponding turn-on switching energy loss (Eon) and a corresponding turn-off switching energy loss (Eoff);
wherein, after the Eon and Eoff are determined for each of the first plurality of different sets of test parameters, the one or more processing elements identifies a sub-range of the first plurality of different sets of test parameters in which the Eon and Eoff are lower than in others of the first plurality of different sets of test parameters;
wherein the one or more processing elements creates a second plurality of different sets of test parameters covering the identified sub-range of the first plurality of different sets of test parameters, each of the second plurality of different sets of test parameters comprising a gate turn-on order for the first and second power semiconductor switches, a gate turn-off order for the first and second power semiconductor switches, a delay on duration, and a delay off duration;
wherein the second plurality of different sets of test parameters has a second resolution higher than the first resolution of the first plurality of different sets of test parameters;
wherein the one or more storage devices stores the second plurality of different sets of test parameters;
wherein the one or more processing elements retrieve the second plurality of different sets of test parameters one at a time from the one or more storage devices;
wherein the one or more gate drivers receives, for each of the second plurality of different sets of test parameters retrieved by the one or more processing elements, one or more signals from the one or more processing elements corresponding to a retrieved set of test parameters and turns the first and second power semiconductor switches on and off according to the retrieved set of test parameters;
wherein the data capture device captures, for each of the first plurality of different sets of test parameters retrieved by the one or more processing elements, data from the first and second power semiconductor switches as the first and second power semiconductor switches turn on and off;
wherein, for each of the second plurality of different sets of test parameters retrieved by the one or more processing elements, the one or more processing elements analyzes the captured data to determine at least a corresponding turn-on switching energy loss (Eon) and a corresponding turn-off switching energy loss (Eoff); and
wherein the one or more processing elements determines which of the second plurality of different sets of test parameters corresponds to a lowest Eon and a lowest Eoff.

2. The system of claim 1, wherein the one or more processing elements comprises a first processing element to retrieve the first plurality of different sets of test parameters one at a time from the one or more storage devices and a second processing element to provide the one or more signals corresponding to a retrieved set of test parameters to the one or more gate drivers.

3. The system of claim 2, wherein the first processing element comprises a personal computer and the second processing element comprises a microcontroller.

4. The system of claim 1, wherein the data capture device comprises an oscilloscope.

5. The system of claim 1, wherein the first power semiconductor switch comprises a silicon carbide transistor and the second power semiconductor switch comprises an insulated-gate bipolar transistor.

6. A method for dynamically characterizing switching behavior of power semiconductors, the method comprising:
storing, in one or more storage devices, a first plurality of different sets of test parameters to be tested on a first power semiconductor switch of a first type and a second power semiconductor switch of a second type, each of the first plurality of different sets of test parameters comprising a gate turn-on order for the first and second power semiconductor switches, a gate turn-off order for the first and second power semiconductor switches, a delay on duration, and a delay off duration, the first plurality of different sets of test parameters having a first resolution;
retrieving, by one or more processing elements, the first plurality of different sets of test parameters one at a time from the one or more storage devices;
for each of the first plurality of different sets of test parameters retrieved by the one or more processing elements, receiving, by one or more gate drivers, one or more signals from the one or more processing elements corresponding to a retrieved set of test parameters;
turning, by the one or more gate drivers, the first and second power semiconductor switches on and off according to the retrieved set of test parameters;
for each of the first plurality of different sets of test parameters retrieved by the one or more processing elements, capturing, by a data capture device to, data from the first and second power semiconductor switches as the first and second power semiconductor switches turn on and off;
for each of the first plurality of different sets of test parameters retrieved by the one or more processing elements, analyzing, by the one or more processing elements, the captured data to determine at least a corresponding turn-on switching energy loss (Eon) and a corresponding turn-off switching energy loss (Eoff);
after the Eon and Eoff are determined for each of the first plurality of different sets of test parameters, identifying, by the one or more processing elements, a sub-range of the first plurality of different sets of test parameters in which the Eon and Eoff are lower than in others of the first plurality of different sets of test parameters;
creating, by the one or more processing elements, a second plurality of different sets of test parameters covering the identified sub-range of the first plurality of different sets of test parameters, each of the second plurality of different sets of test parameters comprising a gate turn-on order for the first and second power semiconductor switches, a gate turn-off order for the first and second power semiconductor switches, a delay on duration, and a delay off duration, the second plurality of different sets of test parameters having a second resolution higher than a first resolution of the first plurality of different sets of test parameters;
storing, by the one or more storage devices, the second plurality of different sets of test parameters;
retrieving, by the one or more processing elements, the second plurality of different sets of test parameters one at a time from the one or more storage devices;
for each of the second plurality of different sets of test parameters retrieved by the one or more processing elements, receiving, by the one or more gate drivers receives, one or more signals from the one or more processing elements corresponding to a retrieved set of test parameters;
turning, by the one or more gate drivers, the first and second power semiconductor switches on and off according to the retrieved set of test parameters;
for each of the second plurality of different sets of test parameters retrieved by the one or more processing elements, capturing, by the data capture device, data from the first and second power semiconductor switches as the first and second power semiconductor switches turn on and off;
for each of the second plurality of different sets of test parameters retrieved by the one or more processing elements, analyzing, by the one or more processing elements, the captured data to determine at least a corresponding turn-on switching energy loss (Eon) and a corresponding turn-off switching energy loss (Eoff); and
determining, by the one or more processing elements, which of the second plurality of different sets of test parameters corresponds to a lowest Eon and a lowest Eoff.

7. The method of claim 6, wherein the one or more processing elements comprises a first processing element to retrieve the first plurality of different sets of test parameters one at a time from the one or more storage devices and a second processing element to provide the one or more signals corresponding to a retrieved set of test parameters to the one or more gate drivers.

8. The method of claim 7, wherein the first processing element comprises a personal computer and the second processing element comprises a microcontroller.

9. The method of claim 6, wherein the data capture device comprises an oscilloscope.

10. The method of claim 6, wherein first power semiconductor switch comprises a silicon carbide transistor and the second power semiconductor switch comprises an insulated-gate bipolar transistor.

11. A busbar assembly comprising:
a front busbar having an elongated top conductor, and elongated middle conductor substantially parallel to the top conductor, and an elongated bottom conductor substantially parallel to the top conductor and the middle conductor;
a planar rear busbar positioned substantially parallel to the front busbar and electrically connected to the bottom conductor of the front busbar; and
a planar insulator positioned between the front busbar and the rear busbar;
wherein the front busbar is adapted to receive a plurality of high side switching devices mounted to the top conductor and the middle conductor; and
wherein the front busbar is adapted to receive a plurality of low side switching devices mounted to the middle conductor and the bottom conductor.

12. The busbar assembly of claim 11, wherein the front busbar comprises one or more top removable or severable side bars connected to the top conductor and the middle conductor, and one or more bottom removable or severable side bars connected to the middle conductor and the bottom conductor.

13. The busbar assembly of claim 11, wherein the middle conductor comprises a middle-top conductor and a middle-bottom conductor with a conductive bridge therebetween;
wherein at least a partial length gap is defined between the middle-top conductor and the middle-bottom conductor; and
wherein the conductive bridge is adapted to receive a conductive wire wrapped therearound to form a Rogowski coil.

14. The busbar assembly of claim 13, wherein a plurality of mounting recesses are defined in each of the top conductor, the middle-top conductor, the middle-bottom conductor, and the bottom conductor of the front busbar;
wherein the plurality of mounting recesses defined in the top conductor and the middle-top conductor are adapted to receive respective mounting flanges of the high side switching devices; and
wherein the plurality of mounting recesses defined in the middle-bottom conductor and the bottom conductor are adapted to receive respective mounting flanges of the low side switching devices.

15. The busbar assembly of claim 14, wherein the plurality of mounting recesses defined in each of the top conductor, the middle-top conductor, the middle-bottom conductor, and the bottom conductor of the front busbar are defined in both a respective front side and a respective rear side of the top conductor, the middle-top conductor, the middle-bottom conductor, and the bottom conductor of the front busbar.

16. The busbar assembly of claim 15, wherein a plurality of wire gaps are defined in each of the middle-top conductor and the bottom conductor of the front busbar, each wire gap being adjacent to a corresponding mounting recess;
wherein the plurality of wire gaps defined in the middle-top conductor are adapted to allow connecting wires of respective ones of the high side switching devices to pass therethrough; and
wherein the plurality of wire gaps defined in the bottom conductor are adapted to allow connecting wires of respective ones of the low side switching devices to pass therethrough.

17. The busbar assembly of claim 15, a plurality of inductor connection points are defined in a same corresponding end of each of the top conductor, the middle-top conductor, the middle-bottom conductor, and the bottom conductor of the front busbar.

18. The busbar assembly of claim 11, wherein the top conductor of the front busbar comprises a high voltage connection point; and
wherein a top edge of the rear busbar comprises a high voltage connection point.
